(19) United States
(12) Patent Application Publication
(10) Pub. No.: US 2013/0092420 A1
(43) Pub. Date: Apr. 18, 2013

(54) EMBEDDED MULTILAYER PRINTED CIRCUIT BOARD AND METHOD

(71) Applicant: MING LI, Shenzhen City (CN)

(72) Inventor: MING LI, Shenzhen City (CN)

(73) Assignees: FOXCONN ADVANCED TECHNOLOGY INC., Tayuan (TW); FUKUI PRECISION COMPONENT (SHENZHEN) CO., LTD., Shenzhen City (CN)

(21) Appl. No.: 13/472,490

(22) Filed: May 16, 2012

(30) Foreign Application Priority Data
Oct. 14, 2011 (CN) 201110311511.1

(51) Int. Cl. H05K 1/02; B29C 65/00

(52) U.S. Cl. 174/251; 156/182

(57) ABSTRACT

An embedded multilayer printed circuit board includes first, second and third circuit substrates, and a flexible circuit substrate. The first circuit substrate includes a first base layer and a first electrically conductive layer. The second circuit substrate includes a second base layer and a second circuit layer. The second circuit substrate also defines a receiving hole. The third circuit substrate includes a third circuit layer, a third base layer, a fourth circuit layer, and an electronic element mounted on the third circuit layer. The third circuit layer and the fourth circuit layer are formed on the opposite sides of the third base layer. The electronic element is received in the receiving hole.

The flexible circuit substrate includes a flexible base layer and a flexible circuit layer. The first circuit layer is electrically connected to the fourth circuit layer by the flexible circuit layer.

### BACKGROUND

1. Technical Field

The present disclosure generally relates to printed circuit boards (PCBs), and particularly, relates to a method for making an embedded multilayer printed circuit board.

2. Description of Related Art

To accommodate the development of miniaturized electronic products with multiple functions, multilayer printed circuit boards are widely used due to their characteristics such as lightness and high-density inter-connectability.

When a multilayer printed circuit board includes discrete devices such as passive components (e.g. resistors or capacitors), the discrete devices have been mounted to the top of the multilayer printed circuit boards by using solder or epoxy type adhesives. The addition of these devices increases the number of steps for making these circuit boards, i.e., the devices must be aligned and adhered to the multilayer board, and connected to a source of power. Furthermore, in order to accommodate a number of discrete devices, the multilayer boards have to be large. Thus, the costs of making such multilayer boards are high.

What is needed, therefore, is a method for manufacturing a embedded multilayer printed circuit board to overcome the above-described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIGS. 1-12 show successive stages in the making of a multilayer printed circuit board according to an exemplary embodiment.

### DETAILED DESCRIPTION

Embodiments will now be described in detail with reference to the drawings.

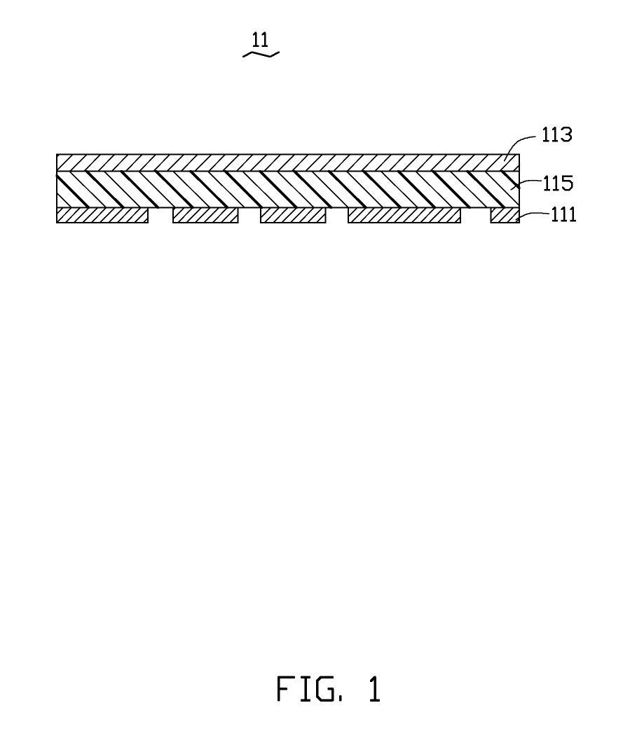

FIGS. 1-12, illustrate a method for making a multilayer printed circuit board (PCB) according to an exemplary embodiment including the following steps.

In step 1, FIG. 1, shows a first circuit substrate 11 is provided. The first circuit substrate 11 can be a single-sided board, a double-sided board, or a multilayer board. In the present embodiment, the first circuit substrate 11 is a double-sided board, and includes a first inner circuit layer 111, a first electrically conductive layer 113, and a first base layer 115 sandwiched between the first inner circuit layer 111 and the first electrically conductive layer 113.

The first inner circuit layer 111 and the first electrically conductive layer 113 are formed on the two opposite sides of the first base layer 115, respectively, and can be made of copper, silver or aluminum. The first inner circuit layer 11 includes a plurality of electrically conductive wires for transmitting electrical signals.

The first base layer 115 can consist of an insulation layer, and can also includes at least one insulation layer and at least one circuit layer, which are alternately stacked. In the illustrated embodiment, the first base layer 115 consists of an insulation layer. The insulation layer can be a rigid insulation material, such as epoxy resin, phenolic resin, or ceramic, for example, and can also be a flexible insulation material, such as Polyimide, Polyethylene terephthalate, or Polyethylene naphthalate, for example.

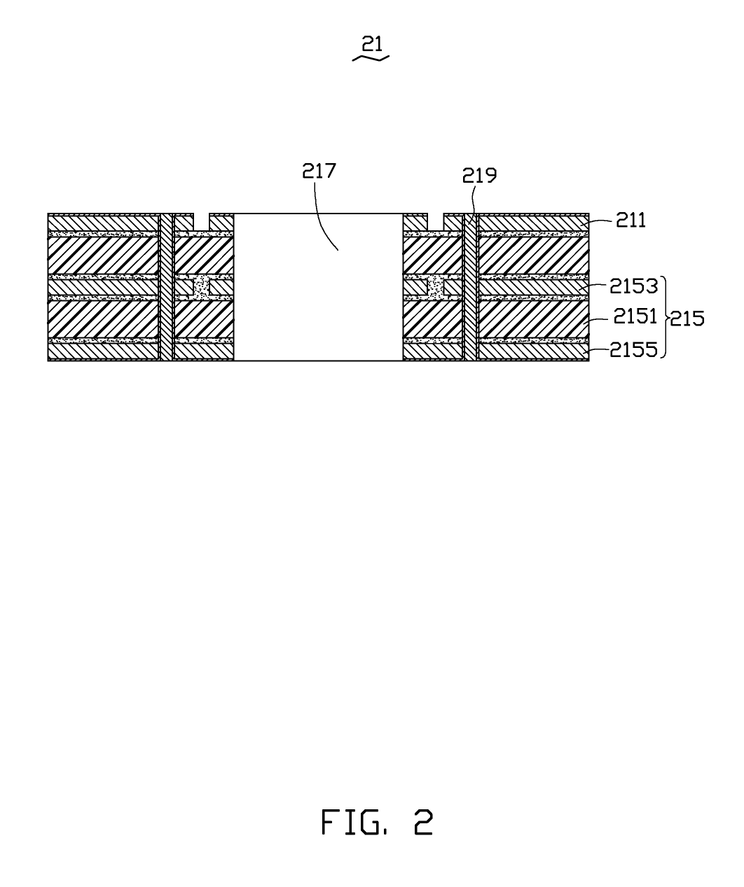

In step 2, FIG. 2, shows a second circuit substrate 21 is provided. The second circuit substrate 21 includes a second base layer 215 and a second circuit layer 211 formed on the second base layer 215. The second circuit substrate 21 defines a receiving hole 217 passing through the second base layer 215 and the second circuit layer 211. The second circuit layer 211 can be made of copper, silver, nickel, aluminum, or an alloy thereof. The second inner circuit layer 211 includes a plurality of electrically conductive wires for transmitting electrical signals.

In the present embodiment, the second base layer 215 is a multilayer structure, and includes two insulation layers 2151, a second inner circuit layer 2153 sandwiched between the two insulation layers 2151, and a second electrically conductive layer 2155. The second circuit layer 211, a second inner circuit layer 2153 and the second electrically conductive layer 2155 are electrically connected to each other by a plurality of plated through holes (not labeled), and the plated through holes are filled with resin 219, such that the following lamination process can be successfully processed.

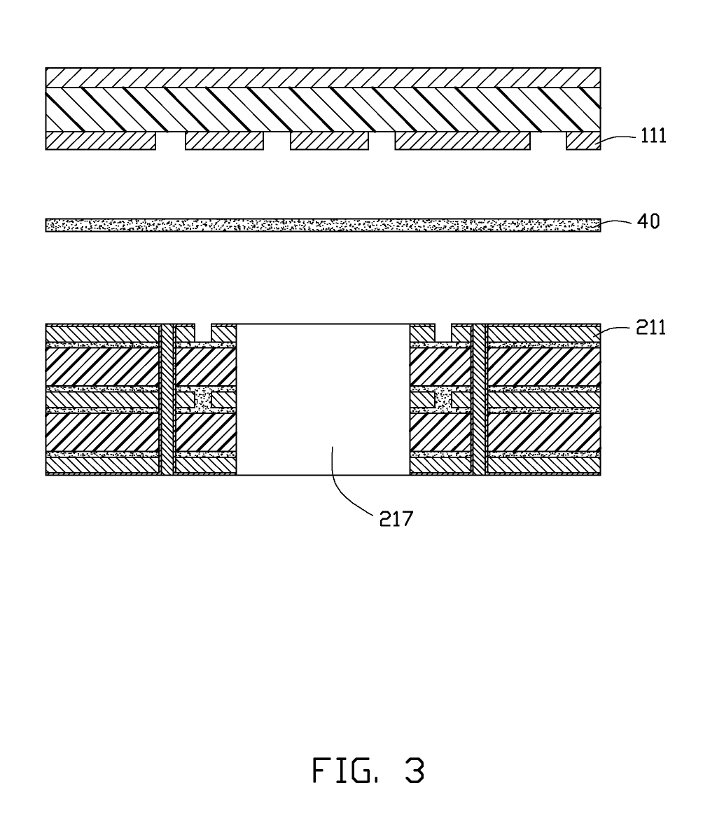

In step 3, FIG. 3, shows a first adhesive sheet 40 is positioned between and in contact with the first inner circuit layer 111 and the second circuit layer 211.

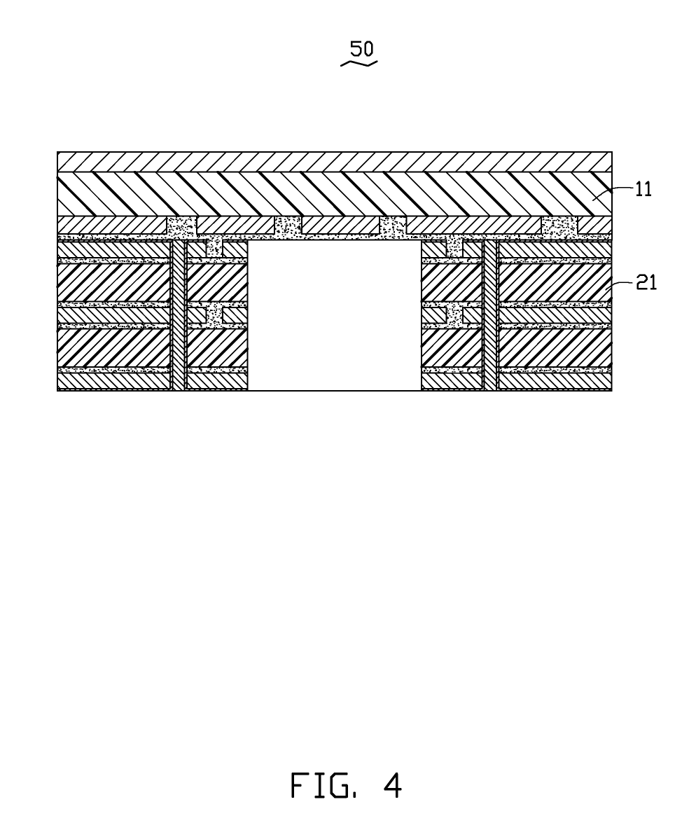

In step 4, FIG. 4, shows the first circuit substrate 11 is laminated onto the second circuit substrate 12 to form a lamination board 50. The lamination board 50 includes the first electrically conductive layer 113, the first base layer 115, the second circuit layer 211, and the second base layer 215 stacked one on another.

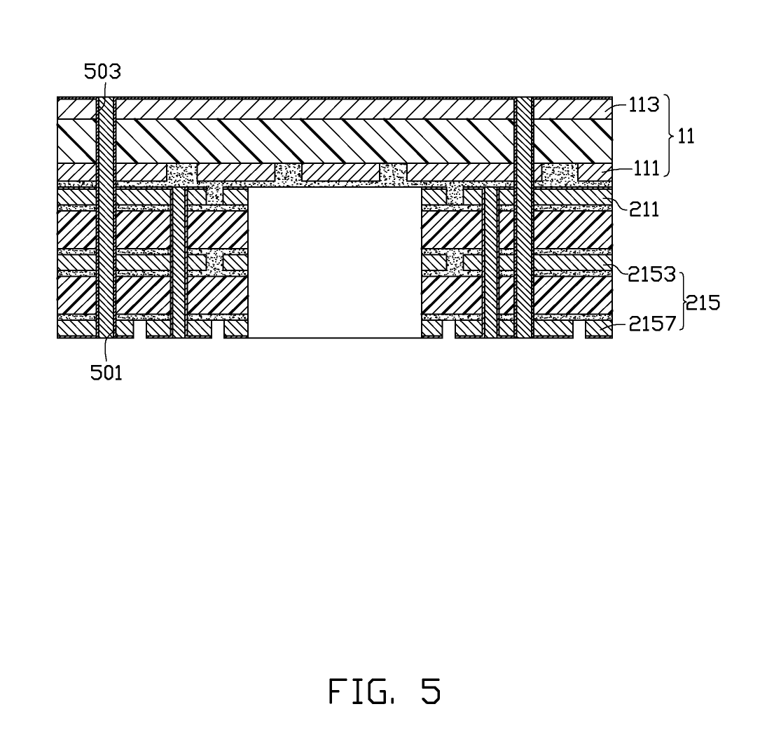

In step 5, FIG. 5, shows two through holes 501 are defined in the lamination board 50 by mechanical drilling process, the through holes 50 are plated to form two plated through holes 503, and each plated through hole 503 is filled with resin, such that the following lamination process can be successfully processed. The plated through holes 503 electrically connect the first circuit substrate 11 and the second circuit substrate 12 to achieve electrical signal transition between the first circuit substrate 11 and the second circuit substrate 12.

In the present embodiment, each through hole 501 is defined by mechanical drilling process. In the mechanical drilling process, a high rotation mechanical drilling pin (not shown) is used to form each through hole 501 in the lamination board 50. Each through hole 501 passes through the first electrically conductive layer 113, the first inner circuit layer 111, the second circuit layer 211, the second inner circuit layer 2153, and the second electrically conductive layer 2155. Each plating through hole 503 is formed by a copper electroplating process in the corresponding through hole 501 to electrically connect the first electrically conductive layer 113, the first inner circuit layer 111, the second circuit layer 211, the second inner circuit layer 2153, and the second electrically conductive layer 2155 to each other, thereby achieving transmission of electrical signals between the first electrically conductive layer 113, the first inner circuit layer 111, the second circuit layer 211, the second inner circuit layer 2153, and the second electrically conductive layer 2155. In alternative embodiments, the through hole 501 may be formed by a laser drilling process. In the laser drilling process, the material in each through hole 501 is removed by laser irradiation, thereby forming the corresponding through hole 501. The laser can be Nd:YAG laser, and can also be carbon dioxide laser. In further alternative embodiments, there may be three plating through holes 503, four plating through holes 503, or more plating through holes 503.

Then, the second electrically conductive layer 2155 is patterned to form a third inner circuit layer 2157. In the present embodiment, the third inner circuit layer 2157 is formed using a DES (Developing, Etching and Stripping) process. Alternatively, the third inner circuit layer 2157 can also be formed using a laser. Understandably, the second electrically conductive layer 2155 may be patterned in step 2.

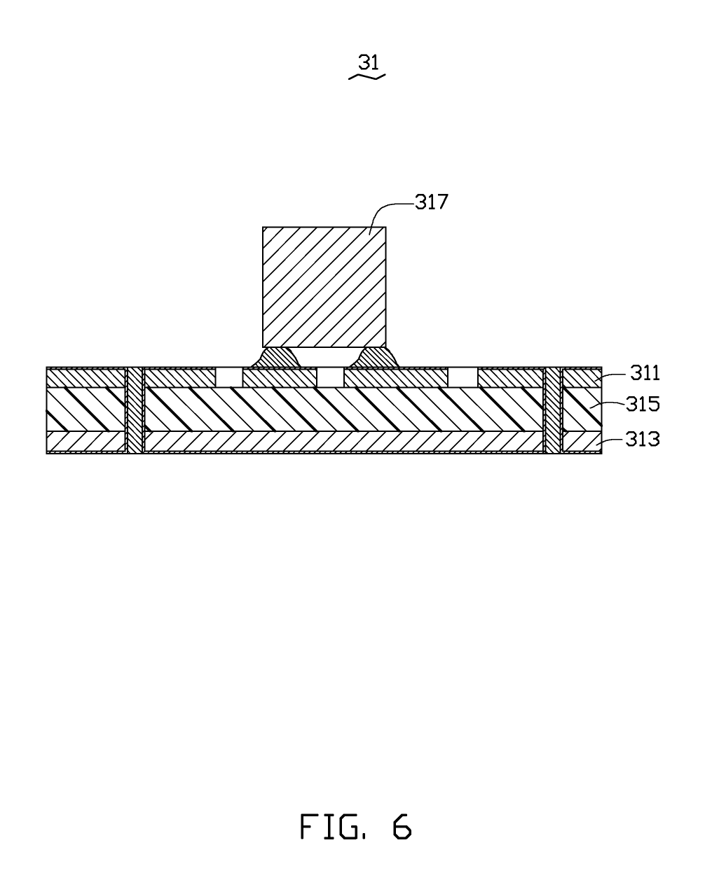

In step 6, FIG. 6, shows a third circuit substrate 31 is provided. The circuit substrate 31 includes a third circuit layer 311, a fourth circuit layer 313, and a third base layer 315.

The third circuit layer 311 and the fourth circuit layer 313 are respectively formed on the two opposite sides of the third base layer 315. The third circuit layer 311 and the fourth circuit layer 313 can be made of copper, silver, nickel or an alloy thereof. The third circuit layer 311 includes a plurality of electrically conductive circuits for transmitting electrical signals.

In the present embodiment, the third circuit layer 311 is electrically connected to the fourth circuit layer 313 by plated through holes (not labeled), and the plated through holes are filled with resin, such that the following lamination process can be successfully processed.

The third base layer 315 can consist of an insulation layer, and can also include at least one insulation layer and at least one circuit layer. In the illustrated embodiment, the third base layer 315 consists of an insulation layer.

Then, an electronic element 317 is mounted on the third circuit layer 311. The electronic element 317 can be a passive element, and can also be an active element. The electronic element 317 can be mounted on the third circuit layer 311 by Flip-chip technology, and can also be mounted on the third circuit layer 311 by surface mounted technology. In the present embodiment, the electronic element 317 is a capacitor, and is mounted on the third circuit layer 311 by Flip-chip technology.

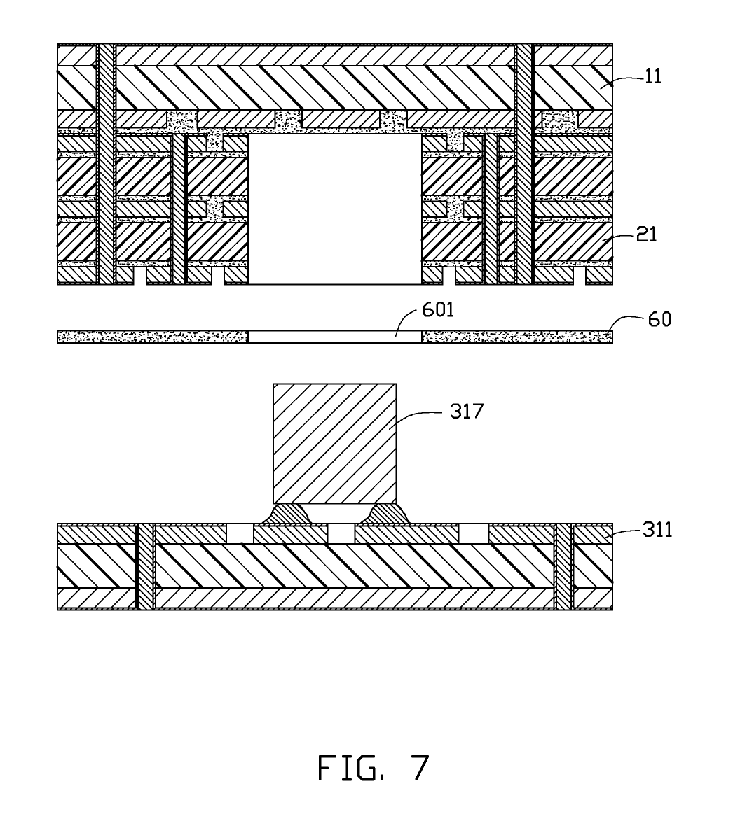

In step 7, FIG. 7, shows a second adhesive sheet 60 is positioned between and in contact with the second base layer 215 of the lamination board 50 and the third circuit layer 311. A through hole 601 is defined in the second adhesive sheet 60, such that the electronic element 317 easily passes through the second adhesive sheet 60. In the present embodiment, an insulation adhesive (not labeled) is first filled in the receiving hole 217, such that insulation adhesive can easily fill a gap between the receiving hole 217 and the electronic element 317.

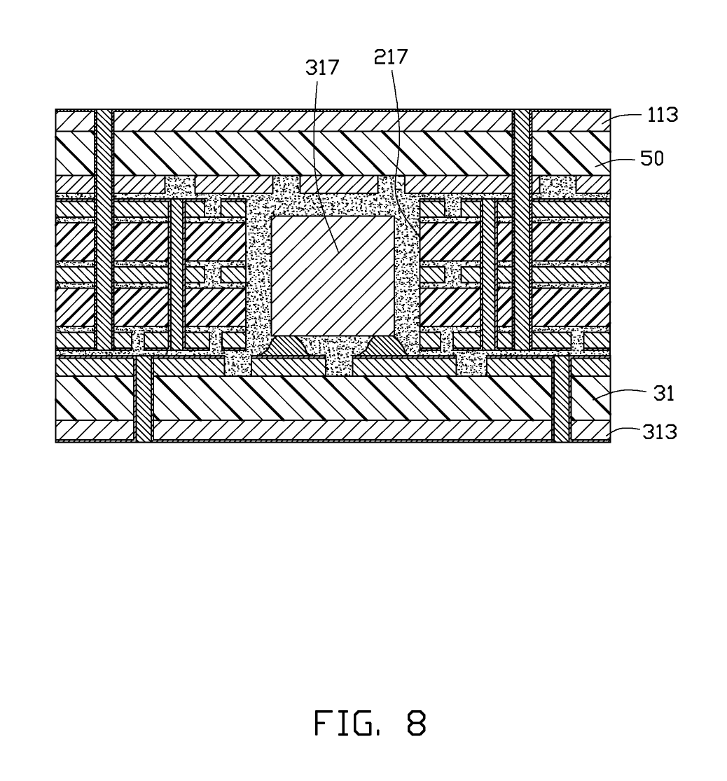

In step 8, FIG. 8, shows the electronic element 317 is aligned with the receiving hole 217, and the lamination board is laminated onto the third circuit substrate 31, such that the electronic element 317 is received in the receiving hole 217.

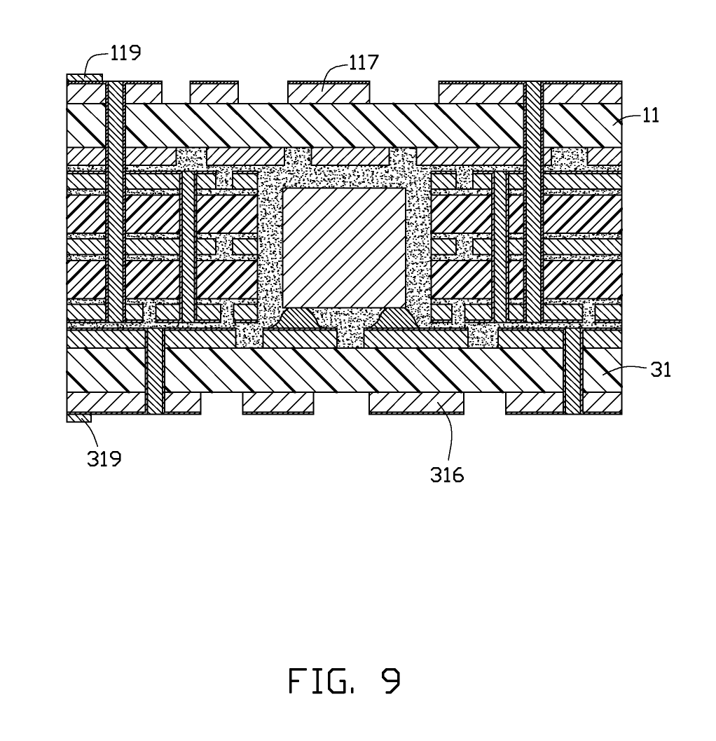

In step 9, FIG. 9, shows the first electrically conductive layer 113 and the fourth electrically conductive layer 313 are patterned, thereby respectively forming a first circuit layer 117 and a second circuit layer 316. The first circuit layer 117 and the second circuit layer 316 can be formed by using the DES process, and can also be formed using a laser. In the present embodiment, the first circuit layer 117 and the second circuit layer 316 are formed by using the DES process, and the first circuit layer 117 and the second circuit layer 316 respectively includes a first connection terminal 119 and a second connection terminal 319. The first connection terminal 119 and the second connection terminal 319 are golden fingers.

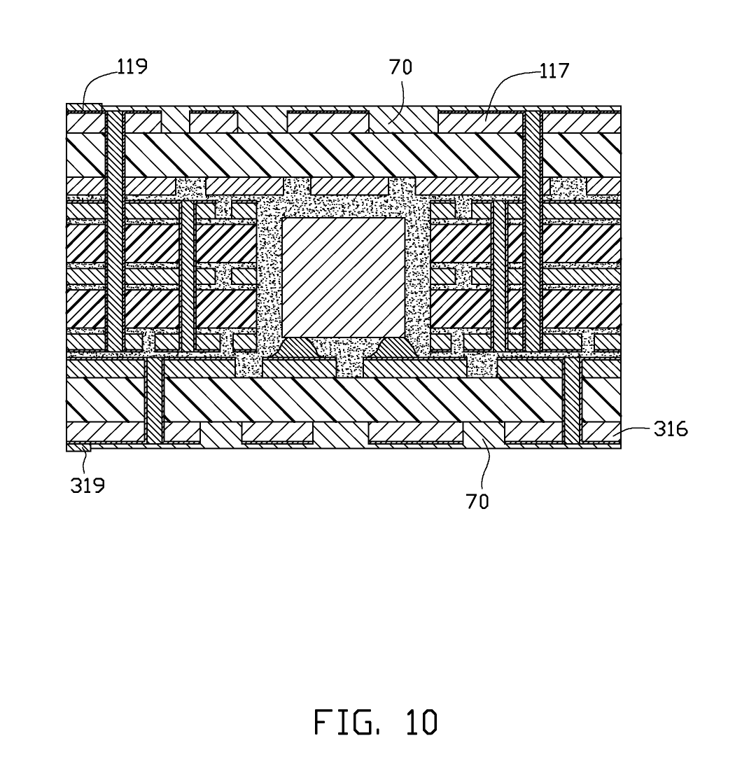

In step 10, FIG. 10, shows solder masks 70 are respectively formed on the first circuit layer 117 and the fourth circuit layer 316, such that the first circuit layer 117 and the fourth circuit layer 316 can be protected from damage.

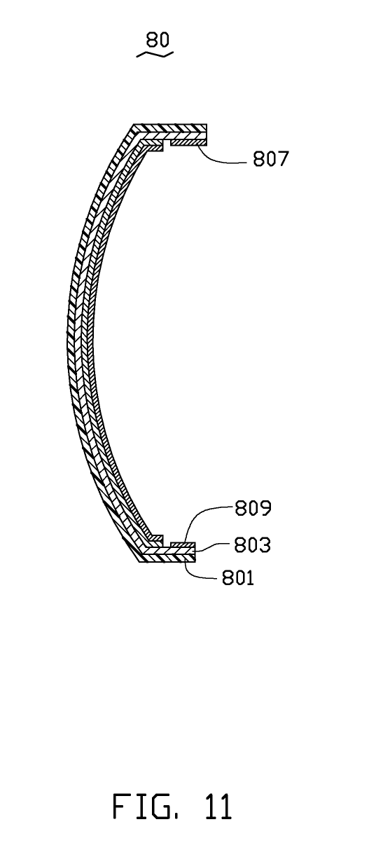

In step 11, FIG. 11, shows a flexible circuit substrate 80 is provided. The flexible circuit substrate 80 includes a flexible base layer 801, and a flexible circuit layer 803 formed on the flexible base layer 801. The flexible circuit layer 801 can be made of Polyimide, Polyethylene terephthalate, Polyethylene naphthalate, or polymer. In the present embodiment, the flexible circuit substrate 80 is made of Polyimide. The flexible circuit layer 803 includes a third connection terminal 807 and a fourth connection terminal 809 opposite to the third connection terminal 807. The third connection terminal 807 and the fourth connection terminal 809 are at the opposite ends of the flexible base layer 801. In the present embodiment, the third connection terminal 807 and the fourth connection terminal 809 are golden fingers.

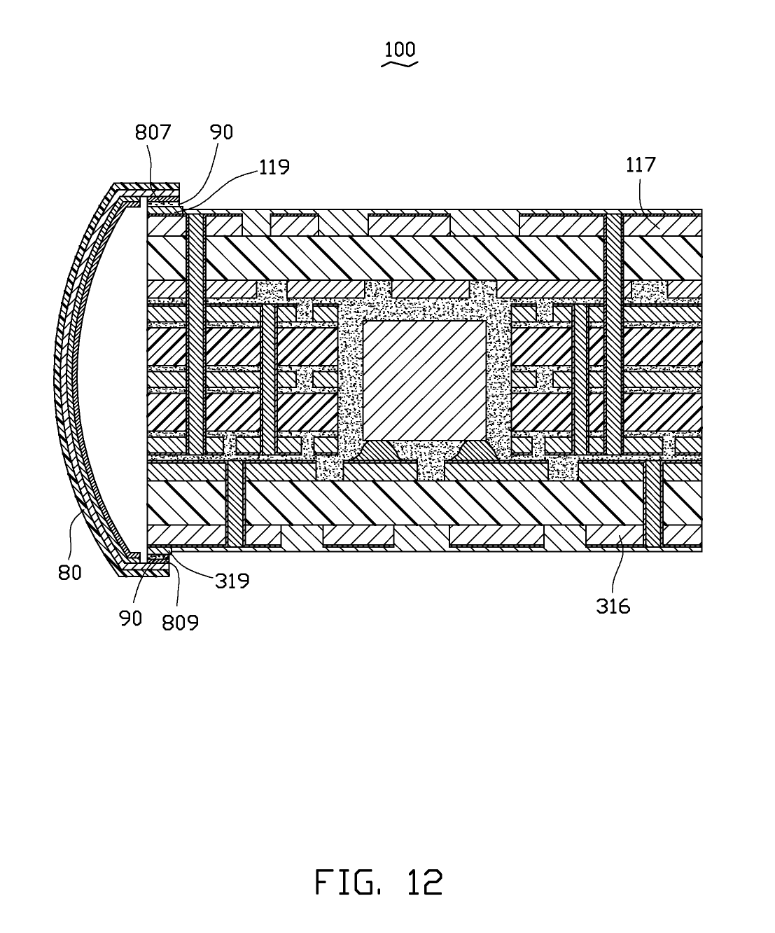

In step 12, FIG. 12, shows the first circuit layer 117 is electrically connected to the fourth circuit layer 316 using the flexible circuit layer 803, thereby forming the embedded multilayer PCB 100.

In the present embodiment, the first connection terminal 319 is electrically connected to the third connection terminal 807 via anisotropic conductive adhesive 90, and the second connection terminal 319 is electrically connected to the fourth connection terminal 809 via anisotropic conductive adhesive 90. In alternative embodiments, the first connection terminal 319 is electrically connected to the third connection terminal 807 via soldering, and the second connection terminal 319 is electrically connected to the fourth connection terminal 809 via soldering. In further alternative embodiments, the first connection terminal 319 is electrically connected to the third connection terminal 807 via electrical wires, and the second connection terminal 319 is electrically connected to the fourth connection terminal 809 via electrical wires.

FIG. 1 to FIG. 12, illustrate the embedded multilayer PCB 100 made by the above method including the first circuit substrate 11, the second circuit substrate 21, the first adhesive sheet 40 sandwiched between the first circuit substrate 11 and the second circuit substrate 12, the third circuit substrate 31, the second adhesive sheet 60 sandwiched between the second circuit substrate 21 and the third circuit substrate 31, and the flexible circuit substrate 80.

The first circuit substrate 11 includes the first inner circuit layer 111, the first circuit layer 117, and the first base layer 115. The first circuit layer 117 includes the first connection terminal 119. The first inner circuit layer 111 and the first circuit layer 117 are positioned at the two opposite sides of the first base layer 115.

The second circuit substrate 21 includes the second circuit layer 211, and the second base layer 215. The receiving hole 217 is defined in the second circuit substrate 21, and passes through the second circuit layer 211 and the second base layer 215. The second base layer 215 includes two insulation layers 2151, the second inner circuit layer 2153 sandwiched between the two insulation layers 2151, and the second electrically conductive layer 2155. The second circuit layer 211, the second inner circuit layer 2153 and the second electrically conductive layer 2155 are electrically connected to each other by a plurality of plated through holes, and the plated through holes are filled with resin 219, such that the following lamination process can be successfully processed.

The first adhesive sheet 40 is positioned between the first inner circuit layer 111 and the second circuit layer 211, and the first circuit layer 117 is electrically connected to the second circuit layer 211 via the plated through hole 503.

The third circuit substrate 31 includes the third circuit layer 311, the fourth circuit layer 316, the third base layer 315, and the electronic element 317 mounted on the third circuit layer 311. The third circuit layer 311 and the fourth circuit layer 315 are positioned at the opposite sides of the third base layer 315, and the third circuit layer 311 is electrically connected to the fourth circuit layer 315 via plated through hole. The fourth circuit layer 316 includes the second connection terminal 319.

The second adhesive sheet 60 is sandwiched between the third circuit layer 31 and the second circuit substrate 21, and the electronic element 317 is received in the receiving hole 217.

The flexible circuit substrate 80 includes a flexible base layer 801, and the flexible circuit layer 803 formed on the flexible base layer 801. The flexible circuit layer 803 includes the third connection terminal 807 and the fourth connection terminal 809 opposite to the third connection terminal 807.

The first connection terminal 319 is electrically connected to the third connection terminal 807 via anisotropic conductive adhesive 90, and the second connection terminal 319 is electrically connected to the fourth connection terminal 809 via the anisotropic conductive adhesive 90.

In the present method for making the embedded multilayer PCB 100, the flexible circuit board 80 is used to electrically connect the first circuit substrate 11 and the third circuit substrate 13, and the electronic element 317 is embedded in the second circuit substrate 21. Therefore, the method for making the embedded multilayer PCB 100 is simpler, and the embedded multilayer PCB 100 is smaller. The cost of the embedded multilayer PCB 100 is thus lower. In addition, in the method for making the embedded multilayer PCB 100, the plated through holes 503 only electrically connect the first circuit substrate 11 and the second circuit substrate 12, and not electrically connect the first circuit substrate 11 and the third circuit substrate 13, such that the electronic element 317 are protected to not suffer damage of the current in the plating solution. Stability of the electronic element 317 is thus improved.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for making an embedded multilayer printed circuit board, comprising:
providing a first circuit substrate, the first circuit substrate comprising a first base layer and a first electrically conductive layer formed on the first base layer;
providing a second circuit substrate, the second circuit substrate comprising a second base layer and a second circuit layer formed on the second base layer, the second circuit substrate defining a receiving hole;
laminating the first circuit substrate onto the second circuit substrate to form a lamination board, the lamination board comprising the first electrically conductive layer, the first base layer, the second circuit layer, and the second base layer stacked one on another;
forming plating through holes in the lamination board so as to electrically connect the first circuit substrate and the second circuit substrate;
providing a third circuit substrate, the third circuit substrate comprising a third circuit layer, a third base layer and a fourth electrically conductive layer, the third circuit layer and the fourth electrically conductive layer being formed on the opposite sides of the third base layer, the third circuit layer being electrically connected to the fourth electrically conductive layer;
mounting an electronic element on the third circuit layer;
aligning the electronic element with the receiving hole, and laminating the lamination board onto the third circuit substrate in a manner such that the electronic element is received in the receiving hole;
patterning the first electrically conductive layer and the fourth electrically conductive layer to form a first circuit layer and a fourth circuit layer respectively;
providing a flexible circuit substrate, the flexible circuit substrate comprising a flexible base layer and a flexible circuit layer formed on the flexible base layer, and
electrically connecting the first circuit layer and the fourth circuit layer using the flexible circuit layer to form an embedded multilayer printed circuit board.

2. The method of claim 1, wherein in the step of patterning the first electrically conductive layer and the fourth electrically conductive layer to form a first circuit layer and a fourth circuit layer respectively, the first circuit layer comprises a first connection terminal, and the fourth circuit layer comprises a second connection terminal, the flexible circuit layer further comprises a third connection terminal and a fourth connection terminal at an opposite side thereof to the third connection terminal, in the step of electrically connecting the first circuit layer and the fourth circuit layer by the flexible circuit layer to form an embedded multilayer printed circuit board, the first connection terminal is electrically to the third connection terminal, and the second connection terminal is electrically to the fourth connection terminal.

3. The method of claim 1, further comprising forming solder masks on the first circuit layer and the fourth circuit layer respectively.

4. The method of claim 1, wherein the step of forming plating through holes comprises:
defining through holes in the lamination board, and
plating the through holes to forming the plating through hole, thereby electrically connecting the first circuit substrate and the second circuit substrate.

5. The method of claim 1, wherein before laminating the first circuit substrate onto the second circuit substrate, a first adhesive sheet is positioned between the first base layer and the second circuit layer.

6. The method of claim 1, wherein before laminating the lamination board onto the third circuit substrate, a second adhesive sheet is positioned between the lamination board and the third circuit layer, and insulation material is filled into the receiving hole.

7. The method of claim 1, wherein the second base layer comprises at least one insulation layer and at least one inner circuit layer, the at least one insulation layer and the at least one inner circuit layer are alternately stacked one on another, and electrically connected to each other via the plating through holes.

8. An embedded multilayer printed circuit board comprising:
a first circuit substrate, the first circuit substrate comprising a first base layer and a first electrically conductive layer formed on the first base layer;
a second circuit substrate, the second circuit substrate comprising a second base layer and a second circuit layer, the second circuit substrate defining a receiving hole;
a third circuit substrate, the third circuit substrate comprising a third circuit layer, a third base layer, a fourth circuit layer, and an electronic element mounted on the third circuit layer, the third circuit layer and the fourth circuit layer being formed on the opposite sides of the third base layer, the third circuit layer being electrically connected to the fourth circuit layer, and the electronic element being received in the receiving hole, and
a flexible circuit substrate, the flexible circuit substrate comprising a flexible base layer and a flexible circuit layer formed on the flexible base layer, and the first circuit layer being electrically connected to the fourth circuit layer through the flexible circuit layer.

9. The embedded multilayer printed circuit board of claim 8, further comprising a first adhesive sheet sandwiched between the first circuit layer and the second base layer, a second adhesive sheet sandwiched between the second base layer and the third circuit layer, and insulation material filled in the receiving hole.

10. The embedded multilayer printed circuit board of claim 8, wherein the first circuit layer further comprises a first connection terminal, the fourth circuit layer further comprises a second connection terminal, the flexible circuit layer further comprises a third connection terminal and a fourth connection terminal at an opposite side thereof to the third connection terminal, the first connection terminal is electrically connected to the third connection terminal, and the second connection terminal is electrically connected to the fourth connection terminal.

11. The embedded multilayer printed circuit board of claim 8, wherein the second base layer is a multilayer structure, and comprises at least one insulation layer and at least one inner circuit layer, and the at least one insulation layer and the at least one inner circuit layer are alternately stacked one on another, and electrically connected to each other via the plating through holes.
